(19) United States
(12) Patent Application Publication
(10) Pub. No.: US 2007/0082511 A1
(43) Pub. Date: Apr. 12, 2007

(54) Signal processing equipment

(76) Inventor: Nobuyuki Kurihara, Ota-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/493,523

(22) Filed: Jul. 27, 2006

(30) Foreign Application Priority Data
Jul. 29, 2005 (JP) 2005-221962

(51) Int. Cl. H05K 1/00

(52) U.S. Cl. 439/65

(57) ABSTRACT

According to one embodiment, signal processing equipment comprising a second circuit conducting signal processing by the first supply voltage generated in the first circuit, a fourth circuit conducting signal processing by the second supply voltage generated in the third circuit, a standard ground terminal to which each ground terminal of the second and fourth circuits connect, and a circuit board leading the first and second supply voltage generated in the first and third circuits to the second and fourth circuits respectively, and forming a plain ground pattern to which each ground terminal from the first to fourth circuits connects.

### CROSS-REFERENCE TO RELATED APPLICATIONS

This application is based upon and claims the benefit of priority from Japanese Patent Application No. 2005-221962, filed Jul. 29, 2005, the entire contents of which are incorporated herein by reference.

### BACKGROUND

1. Field

One embodiment of the invention relates to signal processing equipment which is used and particularly suited for rear-projection television receiving devices, etc., projecting image light from the backside of the screen.

2. Description of the Related Art

As is generally known, rear-projection television receiving devices as in the title are mainly equipped with a signal processing control part (also referred to as a chassis) which conducts the restoration process of image signals from television broadcasting signals, motion control for the overall receiving device, supply of electricity to each part, etc., and an optical engine which converts the image signal restored at this signal processing control part and projects it onto the backside of the screen.

The abovementioned signal processing control part is comprised to store multiple types of circuit boards in the housing, such as a circuit board which conducts motion control for the overall receiving device or receives broadcasting signals, etc., a circuit board which conducts a scaling process for image signals or signal processing of I/P (interlace/progressive) conversion, etc., a circuit board which conducts analog signal processing of analog tuners, etc., a circuit board which generates a power supply for the optical engine, and a circuit board which generates a power supply to each circuit board, etc.

In this case, the supplying of power from a circuit board that generates power to a circuit board to be supplied power is conducted by connecting with an electric wire. Consequently, particularly because a ground (GND) terminal to be the standard electric point of each circuit board is connected by the electric wire, a huge GND loop across each circuit board is subsequently formed, performance for EMI (electromagnetic interference) becomes easily variable, and stabilized image display performance cannot be obtained.

Japanese Published Unexamined Patent Application No. 2002-289991 discloses a structure to facilitate realization of low EMI by arranging connecting parts between boards which are comprised of digital signal terminal rows coordinated to consist of a semiconductor IC with a terminal order and ground terminal rows arranged opposite this in which the digital signal terminal rows face up towards the signal terminal of the semiconductor IC for every semiconductor IC, and connecting with each semiconductor IC without crossed wiring.

However, the abovementioned Japanese Published Unexamined Patent Application No. 2002-289991 neither considers the fact that performance for EMI varies due to the GND terminal of each circuit board being connected by electric wire and a huge GND loop across each circuit board being formed, nor describes any measures for it.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1A and FIG. 1B show, respectively, an embodiment of the present invention illustrating a rear-projection television receiving device;

FIG. 2 is an oblique perspective FIG. illustrating the structure of the signal processing control part of the rear-projection television receiving device in said embodiment;

FIG. 3 shows figures illustrating the structure and connection status of each circuit board configuring signal processing control parts in said embodiment; and

FIG. 4 is an equivalent circuit schematic illustrating the relation of the electrical connection of each circuit board in said embodiment.

### DETAILED DESCRIPTION

Various embodiments according to the invention will be described hereinafter with reference to the accompanying drawings. In general, according to one embodiment of the invention, signal processing equipment comprising: a second circuit conducting signal processing by the first supply voltage generated in the first circuit; a fourth circuit conducting signal processing by the second supply voltage generated in the third circuit; a standard ground terminal to which each ground terminal of the second and fourth circuits connect; and a circuit board leading the first and second supply voltage generated in the first and third circuits to the second and fourth circuits respectively, and forming a plain ground pattern to which each ground terminal from the first to fourth circuits connects.

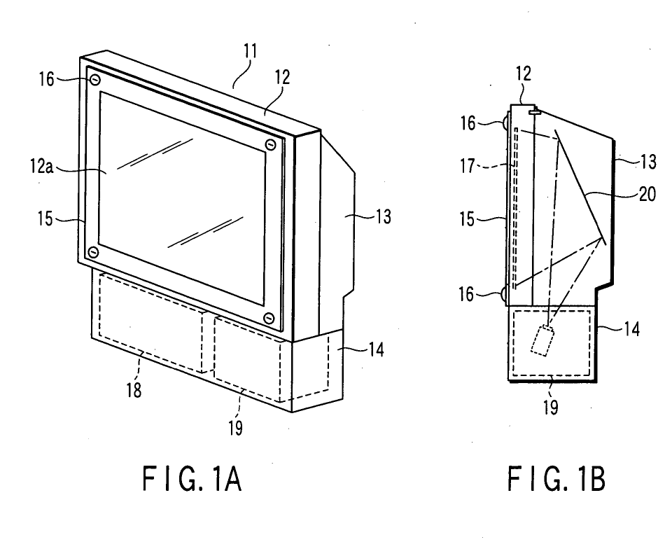

In other words, FIG. 1A and FIG. 1B show a rear-projection television receiving device 11 as the image display device explained in this embodiment.

This rear-projection television receiving device 11 is comprised of a display part 12 which displays images, a rear part 13 which covers one surface of this display part 12, and a supporting part 14 which supports said display part 12 and rear part 13.

Further, on said display part 12, a protector 15 is attached by a screw 16 to cover the display surface 12a. This protector 15, for example, is comprised of a transparent or translucent plastic plate in order to protect the screen 17 in the display part 12, or enhance the contrast and protect the eyes of viewers via an optical filter mechanism.

Also, said supporting part 14 is equipped with a signal processing control part 18 which conducts the restoration process of image signals from television broadcasting signals, motion control for the overall receiving device, supply of electricity to each part, etc., and an optical engine 19 which converts and ejects image signals restored in this signal processing control part 17. The image light ejected from this optical engine 19 is reflected by a mirror 20 installed in said rear part 13, and projected on the back face of a screen 17.

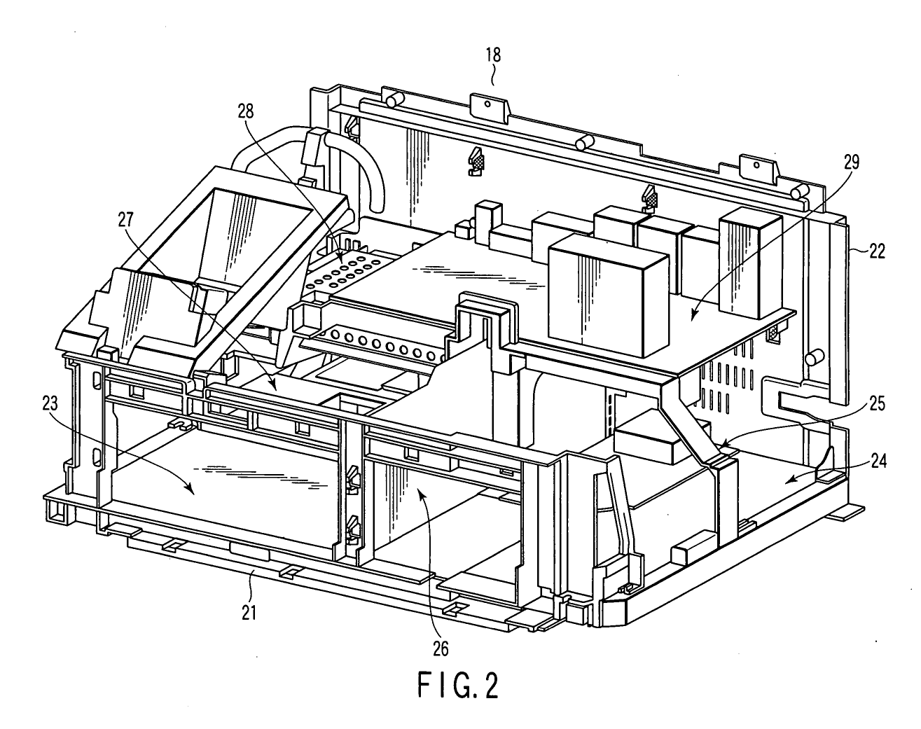

FIG. 2 shows a structure of said signal processing control part 18. This signal processing control part 18 is equipped with a bottom iron plate 21, and a rear iron plate 22 which is erected vertically from the edge of the backside of this bottom iron plate 21.

Moreover, on this bottom iron plate 21, a main power supply board 23 on one side, a sub-power supply board 24 on the other side, and a tuner board 25 on the backside are respectively installed against the surface of this bottom iron plate 21. Also, near the countercurrent terminal part between the main power supply board 23 and the sub-power supply board 24, a motherboard 26 is erected and supported vertically.

Furthermore, on the main power supply board 23, a digital processing board 27 is installed opposite the surface at a prescribed interval, and on this digital processing board 27, a signal processing board 28 is installed opposite the surface at a prescribed interval. Also, on said tuner board 28, an analog processing board 29 is installed opposite the surface at a prescribed interval.

Herein, said digital processing board 27 is equipped with a CPU (central processing unit) which controls the overall rear-projection television receiving device 11, the receiving circuit of digital broadcasting signals, and the interface circuit which connects i-Link and external devices, etc.

Also, said signal processing board 28 is equipped with a sub-CPU, image processing circuit that generates image signals that are provided to an optical engine 19 via an image scaling process, I/P conversion, etc., and a video color decoder.

Furthermore, said analog processing board 29 is equipped with a select circuit of analog input signals that selects input multiple system analog signals. Said tuner board 25 is equipped with a tuner circuit for analog broadcasting signals.

Also, said main power supply board 23 is equipped with a power supply for the optical engine 19 and a power supply circuit to generate a power supply for the analog circuit. Said sub-power supply board 24 is equipped with a power supply circuit that is continuously on and which generates a power supply to the digital processing board 27 and the signal processing board 28.

Furthermore, said motherboard 26 is equipped with a regulator which generates the necessary voltage to each circuit from a secondary-side output of the main power supply board 23 and the sub-power supply board 24, as well as having a function to transmit digital image signals between the digital processing board 27 and the signal processing board 28.

Herein, the secondary-side ground (GND) of said main power supply board 23 and the secondary-side ground of the sub-power supply board 24 are connected near the motherboard 26, and the connecting point is connected to the bottom iron plate 21.

Further, the secondary-side ground (GND) of the main power supply board 23 and the secondary-side ground of the sub-power supply board 24 are also connected to the motherboard 26 via a connector, and it becomes the standard GND of the regulator formed on the motherboard 26.

In addition, this bottom iron plate 21 becomes the standard ground (solid GND) of the overall signal processing control part 18.

Also, the ground of said digital processing board 27 and the ground of the signal processing board 28 are connected to a rear iron plate 22. This rear iron plate 22 becomes a solid standard ground similar to the bottom iron plate 21 by being connected to the bottom iron plate 21.

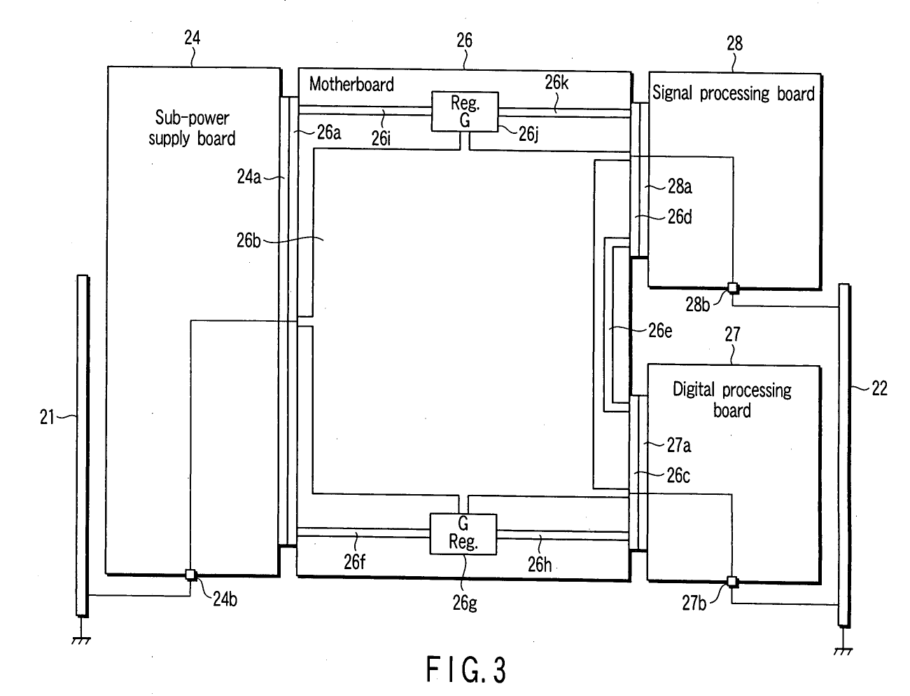

FIG. 3 shows the structure and connection status of said sub-power supply board 24, motherboard 26, digital processing board 27, and signal processing board 28. In other words, the sub-power supply board 24 is electrically connected to the motherboard 26 by a connector 24a installed on one edge that is connected to a connector 26a installed on one edge of the motherboard 26.

Also, a ground terminal 24b to be a secondary-side ground of this sub-power supply board 24 is connected to said bottom iron plate 21 in addition to being connected to a ground pattern 26b of the motherboard 26 via the connectors 24a and 26a.

In contrast, said digital processing board 27 is electrically connected to the motherboard 26 by a connector 27a which is installed on one edge that is connected to a connector 26c which is installed on the other edge. Also, a ground terminal 27b of this digital processing board 27 is connected to said rear iron plate 22 in addition to being connected to the ground pattern 26b of the motherboard 26 via the connectors 27a and 26c.

Furthermore, said signal processing board 28 is electrically connected to the motherboard 26 by a connector 28a which is installed on one edge that is connected to a connector 26d which is installed on the other edge of the motherboard 26. Also, a ground terminal 28b of this signal processing board 28 is connected to the rear iron plate 22 in addition to being connected to the ground pattern 26b of the motherboard 26 via the connectors 28a and 26d.

Moreover, said digital processing board 27 is electrically connected to the signal processing board 28 via the connectors 27a and 26c, a connecting pattern 26e of the motherboard 26, and the connectors 26d and 28a. Herewith, between the digital processing board 27 and the signal processing board 28, digital image signals can be transmitted.

Herein, said motherboard 26 forms a pattern 26f to which electric power for the digital processing board 27 generated in the sub-power supply board 24 is provided via the connectors 24a and 26a, a regulator 26g which generates the necessary voltage from the electric power provided via this pattern 26f, and a pattern 26h to provide voltage generated by this regulator 26g via the connectors 26c and 27a to the digital processing board 27. Further, the ground terminal G of this regulator 26g is connected to the ground pattern 26b of the motherboard 26.

Also, said motherboard 26 forms a pattern 26i to which electric power for the signal processing board 28 generated in the sub-power supply board 24 is provided via the connectors 24a and 26a, a regulator 26j which generates the necessary voltage from electric the power provided via this pattern 26i, and a pattern 26k to provide voltage generated by this regulator 26j via the connectors 26d and 28a to the signal processing board 28. Further, the ground terminal G of this regulator 26j is connected to the ground pattern 26b of the motherboard 26.

Herein, said motherboard 26 forms a plain ground pattern 26b across most of the front and back surfaces. This ground pattern 26b is connected to the bottom iron plate 21 via a connector which is not illustrated, in an integrated state into the signal processing control part 1, and becomes a solid standard ground similar to the bottom iron plate 21.

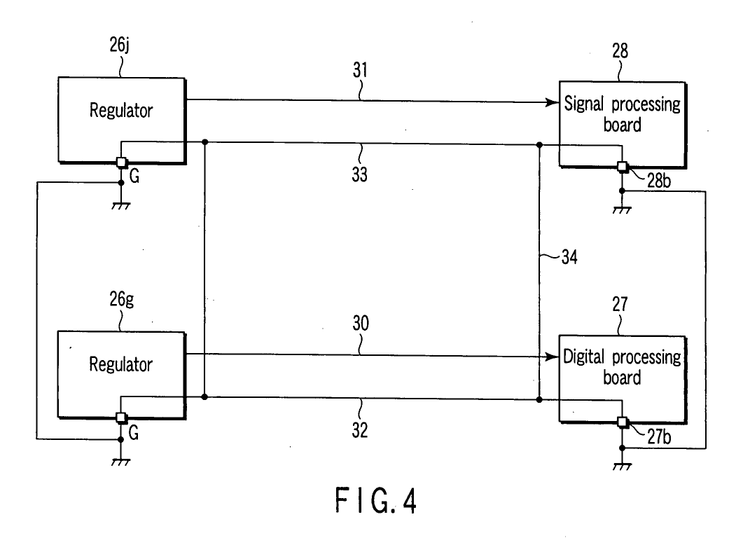

FIG. 4 shows an equivalent circuit illustrating the mutual relation of connections among the regulators 26j, 26g, the digital processing board 27, and the signal processing board 28, for the structure shown in FIG. 3. In other words, voltage generated in said regulator 26g is provided to the digital processing board 27 via a connecting wire 30 corresponding to said pattern 26h. Also, voltage generated in said regulator 26j is provided to the signal processing board 28 via a connecting wire 31 corresponding to said pattern 26k.

Further, by each ground terminal G of the regulators 26j and 26g, each ground terminal 27b and 28b of the digital processing board 27, and the signal processing board 28 being respectively connected to the ground pattern 26b formed in a plain state on the motherboard 26, a structure is created in which a ground line 32 connecting the digital processing board 27 and the regulator 26g as well as a ground line 33 connecting the signal processing board 28 and the regulator 26j are connected at a closer location to the digital processing board 27 and the signal processing board 28 via a connecting wire 34.

Herewith, the GND loop formed between the digital processing board 27 and the signal processing board 28 can be suppressed to be smaller, thus helping with stabilization of the performance for EMI as unnecessary radiation which is leaked out from the digital processing board 27 and the signal processing board 28 can be suppressed.

In other words, because the digital processing board 27 and the signal processing board 28 are respectively loaded with digital devices, radiation leaking out from the operating current is huge. Therefore, by lowering the GND impedance between the digital processing board 27 and the signal processing board 28 and making the GND loop smaller, radiation can be substantially suppressed.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. Signal processing equipment comprising:
a first circuit being configured to generate a first supply voltage;
a second circuit being configured to conduct signal processing by the first supply voltage generated in said first circuit;
a third circuit being configured to generate a second supply voltage;
a fourth circuit being configured to conduct signal processing by the second supply voltage generated in said third circuit;
a standard ground terminal being configured to which each ground terminal of said second and fourth circuits connects; and
a circuit board being configured to lead the first and second supply voltage generated in said first and third circuits to said second and fourth circuits respectively, and form a plain ground pattern to which each ground terminal from said first to fourth circuits connects.

2. Signal processing equipment according to claim 1, wherein
said ground pattern is formed on both sides of said circuit board.

3. Signal processing equipment according to claim 1, wherein
a standard ground terminal is an iron plate supporting said circuit board, and the ground pattern of said circuit board is connected to this iron plate.

4. Signal processing equipment according to claim 1, wherein
said first and third circuits are formed on said circuit board.

5. Signal processing equipment according to claim 1, wherein
said second and fourth circuits are configured to conduct signal processing of digital data.

6. Signal processing equipment according to claim 1, wherein
either said second or fourth circuit is configured to process image signals provided to the optical engine of a projection image display device.
